(19) United States
(12) Patent Application Publication
(10) Pub. No.: US 2015/0245471 A1
(43) Pub. Date: Aug. 27, 2015

(54) ELECTRONIC DEVICE

(71) Applicant: DENSO CORPORATION, Kariya-city (JP)

(72) Inventors: Hirotsugu KATOU, Hekinan-city (JP); Junji SUGIURA, Hekinan-city (JP); Akito ITOU, Kariya-city (JP)

(21) Appl. No.: 14/615,772

(22) Filed: Feb. 6, 2015

(30) Foreign Application Priority Data
Feb. 27, 2014 (JP) 2014-37046

(51) Int. Cl. H05K 1/02; H05K 1/18; H05K 1/11

(52) U.S. Cl. CPC H05K 1/0298; H05K 1/11; H05K 1/181; H05K 2201/10507

(57) ABSTRACT

An electronic device includes a multilayer substrate including a plurality of layers of conductors. The multilayer substrate has a first region and a second region divided in a planar direction of the multilayer substrate. The first region is provided with a main circuit that realizes a predetermined function. The second region is provided to have an additional circuit for adding a function to the predetermined function therein. The first region includes a first wiring for electrically connecting the main circuit to the additional circuit and a connecting portion disposed at an end of the first region adjacent to the second region and extending in the multilayer substrate to correspond to all of the conductors layered to electrically connect the first wiring to any of the conductors. The main circuit is connectable with the additional circuit through the first wiring and the connecting portion.

### CROSS REFERENCE TO RELATED APPLICATION

This application is based on Japanese Patent Application No. 2014-37046 filed on Feb. 27, 2014, the disclosure of which is incorporated herein by reference.

### TECHNICAL FIELD

The present disclosure relates to an electronic device having a first region in which a main circuit for realizing a predetermined function is provided, and a second region to which an additional circuit for adding a function to the predetermined function can be added.

### BACKGROUND

Electronic devices, such as in-vehicle electronic control units (ECU), are generally put into mass production through design changes many times from the early stage of development. Even after the start of the mass production, design changes, such as adding functions, are made. If the arrangements of component parts and wirings are revised for the whole of the substrate of the electronic device every time the design change is made, workloads and manufacturing costs increase. Further, it is necessary to perform noise evaluation and environmental evaluation for the whole of the substrate. Therefore, the workloads and the manufacturing costs further increase.

For example, JP 2005-205814 A discloses an electronic device having a first region (main circuit board) formed with a main circuit for realizing a predetermined function and a second region (function-adding circuit board) to which an additional circuit for realizing addition of a function relative to the predetermined function is to be added. In JP 2005-205814 A, the first region and the second region are separately provided. That is, the first region and the second region are provided by separate circuit boards.

### SUMMARY

In JP 2005-205814 A, since the first region and the second region are separate from each other, even if design changes, such as addition of functions, change of functions, deletion of functions, are necessary during the development or after the start of the mass production, it is possible to change the second region only. Namely, the design change can be performed without adding a change to the first region. For example, a function can be added without adding a change to the first region. In such a case, the workloads in association with the design change reduce, as compared with the case where the whole of the substrate needs to be reviewed. Also, the increase in manufacturing costs can be restricted.

For example, the first region can be made in common for plural types of vehicles or for different grades of the same type of vehicles, and an additional circuit for adding functions can be formed in the second region for vehicles in high class or vehicles of high grade model. When the specification of the first region is common in the plural types of vehicles or the vehicles in the same types but in different grades, the manufacturing costs can be reduced.

In JP 2005-205814 A, however, a connector is necessary to connect the main circuit and the additional circuit. For this reason, the number of component parts increases due to the connector, and the manufacturing costs increase. Further, terminals of the connector are likely to be stressed due to the engagement of the connector and application of external vibrations. Therefore, there is a fear in reliability of the electrical connection between the main circuit and the additional circuit. Since the first region and the second region are provided by separate circuit boards, the number of the circuit boards increases, resulting in the increase in manufacturing costs.

It is an object of the present disclosure to provide an electronic device having a first region for a main circuit and a second region for an additional circuit, which is capable of reducing manufacturing costs and improving reliability in electrical connection.

According to an aspect of the present disclosure, an electronic device includes a multilayer substrate including a plurality of conductors layered. The multilayer substrate has a first region and a second region divided in a planar direction of the multilayer substrate perpendicular to a layered direction of the conductors. The first region is provided with a main circuit that realizes a predetermined function. The second region is provided for having an additional circuit therein for adding a function to the predetermined function. The first region includes a first wiring for electrically connecting the main circuit to the additional circuit, and a connecting portion electrically connected to the first wiring. The connecting portion is disposed at an end of the first region adjacent to the second region and extending in the multilayer substrate to correspond to all of the conductors layered to enable the first wiring to connect to any of the conductors layered. The main circuit is connectable with the additional circuit through the first wiring and the connecting portion.

In the above structure, the first region and the second region are separately provided in the multilayer substrate. In addition, the connecting portion is disposed to extend in the multilayer substrate to correspond to all of the conductors layered, at an end portion of the first region adjacent to the second region. The main circuit is connected to the connecting portion through the first wiring. In this way, the first wiring can be connected to any of the conductors through the connecting portion. Therefore, even if the additional circuit to be added to the second region has any structure or specification, the main circuit and the additional circuit can be electrically connected to each other without changing the specification of the first region. Namely, a function can be added without changing the first region. Evaluations for noise and the like according to a design change such as addition, changing or deletion of a function may be conducted only for the second region. As compared with a case where it is necessary to review the entirety of the substrate, a workload due to the design change of the substrate can be reduced, and an increase in manufacturing costs can be restricted.

Since the first region and the second region are provided in the same substrate, that is, in the common substrate, the manufacturing costs can be reduced, as compared with a structure in which the first region and the second region are provided by separate substrates. Since the main circuit is electrically connectable to the additional circuit through the connecting portion formed in the multilayer substrate. Therefore, a connector, which is a separate part from the substrate, is not necessary to connect between the main circuit and the additional circuit. As such, the number of component parts reduces, and the manufacturing costs reduce. Since the connecting portion formed in the multilayer substrate is used, without using the separate connector, the reliability of electrical connection between the main circuit and the additional circuit improves.

### BRIEF DESCRIPTION OF THE DRAWINGS

The above and other objects, features and advantages of the present disclosure will become more apparent from the following detailed description made with reference to the accompanying drawings, in which like parts are designated by like reference numbers and in which:

FIG. 1 is a diagram illustrating a schematic plan view of an electronic device according to a first embodiment of the present disclosure;

FIG. 2 is a diagram illustrating a cross-sectional view of the electronic device taken along a line II-II in FIG. 1;

FIG. 3 is a diagram illustrating a schematic plan view of the electronic device in a state where functions are added to the state shown in FIG. 1;

FIG. 4 is a diagram illustrating a cross-sectional view of the electronic device taken along a line IV-IV in FIG. 3;

FIG. 5 is a diagram illustrating a schematic plan view of the electronic device in a state where functions are further added to the state shown in FIG. 3; and

FIG. 6 is a diagram illustrating a cross-sectional view of the electronic device taken along a line VI-VI in FIG. 5.

### DETAILED DESCRIPTION

Hereinafter, embodiments of the present disclosure will be described with reference to the drawings.

### First Embodiment

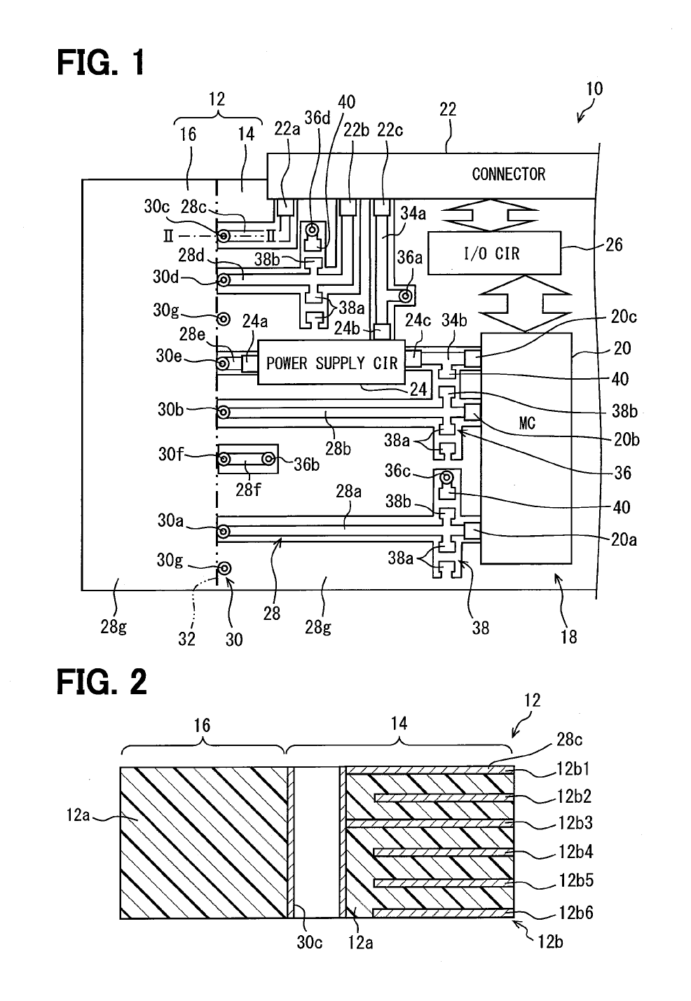

Firstly, a basic structure of an electronic device according to a first embodiment will be described with reference to FIGS. 1 and 2. In the present embodiment, the electronic device is exemplarily configured as an electronic control device for a hybrid vehicle, which has an engine and a motor as driving sources for traveling.

An electronic device 10 shown in FIGS. 1 and 2 is in a state where a main circuit 18 is formed in a first region 14, but an additional circuit is not formed in a second region 16. The electronic device 10 in this state may be used for vehicles of a basic type, among various types of vehicles using the first region 14 in common. Also, the electronic device 10 in this state may be used for a vehicle of a basic grade, among various grades of vehicles of the same type. The electronic device 10 in this state may be used as an electronic device in an early stage of mass production for considering design change after the mass production. The electronic device 10 in this state may be used as an electronic device in a state where any functions as user's options are not added. The electronic device 10 in this state may be an electronic device during development.

An electronic device 10 includes a multilayer substrate 12. The multiplayer substrate 12 is provided by arranging conductors 12b, such as conductors 12b1 to 12b6, in layers in an insulating base material 12a, which is for example made of resin. A direction in which the conductors 12b are layered will be referred to as a layered direction. The layered direction corresponds to an up and down direction in FIG. 2, and is a direction perpendicular to a planar direction of the multilayer substrate 12.

In the present embodiment, the multilayer substrate 12 has a six-layer structure. As an example, signal lines are included in conductors 12b1, 12b2, 12b5 and 12b6, which are on first, second, fifth and sixth layers. A conductor 12b3 on a third layer mainly provides a ground layer. A conductor 12b4 on a fourth layer mainly provides a power supply layer. The multilayer substrate 12 is divided into two regions, such as the first region 14 and the second region 16, in a plane perpendicular to the layered direction (e.g., up and down direction in FIG. 2) of the conductors 12b. In other words, the multilayer substrate 12 has the first region 14 and the second region 16 which are arranged side by side in the planar direction of the multilayer substrate 12, that is, when viewed in a direction along the layered direction of the conductors 12b.

In the first region 14, the main circuit 18 for realizing a predetermined function is formed. The main circuit 18 is a base circuit that is necessary in the electronic device 10 (multilayer substrate 12). For example, the main circuit 18 is a circuit that provides basic functions of an electronic control, as the predetermined function. The main circuit 18 includes a microcomputer 20, a connector 22, a power supply circuit 24, an input and output circuit 26, and the like. In the present embodiment, the main circuit 18 is a circuit that enables to integrally control the entirety of a driving system of the hybrid vehicle.

The microcomputer 20 includes a CPU, a ROM, a RAM, a resistor and the like. The CPU performs various operation processings while using the RAM and the resistor temporarily as a storage area, based on various input signals, such as sensor signals inputted through the connector 22 and the input and output circuit 26, and programs stored in the ROM beforehand. Then, the CPU outputs the operation results to external devices through the input and output circuit 26 and the connector 22.

The connector 22 serves as an externally connecting-terminal to electrically connect the electronic device 10 with another device, such as an external device. The power supply circuit 24 serves as an internal power supply that converts a voltage of an external power supplied to the electronic device 10 through the connector 22 into a predetermined voltage, and supplies the converted power having the predetermined voltage to another component of the electronic device 10. For example, the power supply circuit 24 is supplied with an external power from a secondary battery as an external power supply through the connector 22. The power supply circuit 24 bucks the voltage of the external power to a desired voltage, and supplies the power bucked to the microcomputer 20 and the like.

The first region 14 is provided with a first wiring 28 and a connecting portion 30 to allow electrical connection of the main circuit 18 to an additional circuit formed in the second region 16. The first wiring 28 connects between the main circuit 18 and the connecting portion 30 to electrically connect the main circuit 18 and the additional circuit. The first wiring 28 is configured to include the conductor 12b.

In the present embodiment, the first region 14 includes a plurality of the first wirings 28. Each of the first wirings 28 is constructed to include at least the conductor 12b1 on the first layer. An end of each first wiring 28 is electrically connected to the main circuit 18.

In the present embodiment, the first region 14 includes a plurality of the connecting portions 30. The connecting portions 30 are correspondingly provided for the first wirings 28. The connecting portions 30 are disposed at an end of the first region 14 adjacent to the second region 16. In FIG. 1, a double-dashed chain line indicates a boundary 32 between the first region 14 and the second region 16.

Each of the connecting portions 30 extends through the multilayer substrate 12 at least over all of the layers in which the conductors 12b are formed to enable electrical connection of each of the first wirings 28 to the conductors 12b (12b1 to 12b6) on any layers. That is, each of the connecting portion 30 extends in the multilayer substrate 12 to correspond to all of the conductors 12b layered. In the present embodiment, for example, the connecting portion 30 is provided by a through hole extending through the multilayer substrate 12.

The wall surface defining the through hole is plated, so that the connecting portion 30 enables electrical connection between the conductors 12b on any layers and the additional circuit. In other words, even if any type of additional circuit is formed, that is, even if the additional circuit has any configuration or specification, the additional circuit and the main circuit 18 can be connected to each other through the main circuit 18.

In the present embodiment, the first wirings 28 include signal lines 28a, 28b, 28c and 28d. The signal lines 28a and 28b are connected to terminals 20a and 20b of the microcomputer 20, respectively. The signal lines 28c and 28d are connected to terminals 22a and 22b of the connector 22, respectively.

Further, the first wirings 28 include an internal power supply line 28e and an external power supply line 28f. The internal power supply line 28e is connected to a terminal 24a of the power supply circuit 24. The external power supply line 28f is connected to a terminal 22c of the connector 22 through an external power supply line 34a, through holes 36a and 36b and the conductor 12b4, which serves as the power supply layer. Moreover, the first wirings 28 include a ground pattern 28g.

In the following description, the signal lines 28a to 28d, the internal power supply line 28e, the external power supply line 28f, and the ground pattern 28g are also referred to as the first wirings 28a to 28g.

The external power supply line 34a is a wiring that connects between the terminal 22c of the connector 22 and a terminal 24b of the power supply circuit 24 so as to supply the external power from the external power supply (not shown) to the power supply circuit 24 through the connector 22. The external power supply line 34a is a part of the main circuit 18. The external power supply line 34a is diverged into two lines, one of which is connected to the terminal 24b and the other of which is connected to the through hole 36a. The through holes 36a and 36b penetrate through the multilayer substrate 12. The through hole 36a connects between the external power supply line 34a and the conductor 12b4, which forms the power supply layer. The through hole 36b connects between the conductor 12b4 and the external power supply line 28f. In place of the through holes 36a and 36b, connection vias may be employed.

The ground pattern 28g is disposed as a mat or solid in the first layer of the multilayer substrate 12 to surround the other first wirings 28 (28a to 28f) and the main circuit 18. The ground pattern 28g is connected to terminals (not shown) of the microcomputer 20, the connector 22 and the power supply circuit 24. The ground pattern 28g is also electrically connected to the conductor 12b3, which forms the ground layer, through a through hole (not shown).

Any of the first wirings 28a to 28g are disposed in the first layer of the multilayer substrate 12. The first wirings 28a to 28g are correspondingly connected to the connecting portions 30a to 30g. In the present embodiment, a plurality of the connecting portions 30g is provided for the ground pattern 28g. The connecting portions 30a to 30g are arranged in one line along the boundary 32, within the first region 14, as shown in FIG. 1.

Of the first wirings 28a to 28f, the first wirings 28a, 28b, 28d and 28g are provided with lands 38. On the lands 38, a chip component, such as a resistor and a capacitor, is mounted according to the additional circuit formed in the second region 16. The lands 38 include first lands 38a and second lands 38b. The first lands 38a are disposed between the signal lines 28a, 28b and 28d and the ground pattern 28g.

For example, when a resistor is mounted on a pair of the first lands 38a respectively disposed on the signal line 28a and the ground pattern 28g, the signal line 28a and the ground pattern 28g are electrically connected to each other through the resistor. The second lands 38b are disposed between the signal lines 28a, 28b and 28d and the internal power supply line 34b.

The internal power supply line 34b is a wiring that connects between a terminal 24c of the power supply circuit 24 and a terminal 20c of the microcomputer 20 so as to supply the power having the bucked voltage from the power supply circuit 24 to the microcomputer 20. The internal power supply line 34b forms a part of the main circuit 18.

As shown in FIG. 1, the signal lines 28a and 28d are connected to the internal power supply line 34b through the through holes 36c and 36d and through holes (not shown) connected to the internal power supply line 34b. The internal power supply line 34b is also provided with the land 40 that forms a pair with the second land 38b.

For example, when a resistor is mounted on the second land 38b of the signal line 28a and the land 40 of the internal power supply line 34b, the signal line 28a and the internal power supply line 34b are electrically connected to each other through the resistor.

In this case, the land 38 corresponds to “the land of the first wiring”. For example, in a case where the second lands 38b are provided between the signal lines 28a, 28b and 28d and the internal power supply line 28e, the lands 40 also correspond to “the land of the first wiring”.

In the state shown in FIGS. 1 and 2, the additional circuit is not formed in the second region 16. As shown in FIG. 2, the conductors 12b1, 12b2, 12b5 and 12b6 including the signal lines, the conductor 12b3 forming the ground layer, and the conductor 12b4 forming the power supply layer are not formed in the second region 16. Alternatively, at least one of the conductors 12b3 and 12b4 may be formed in the second region 16. When the at least one of the conductors 12b3 and 12b4 is formed in the second region 16, the strength of the multilayer substrate 12, in particular, the strength of the second region 16 can be increased.

In the state shown in FIGS. 1 and 2, the first wirings 28a to 28f include unused wirings that are not electrically connected to the additional circuit. The unused wirings are processed according to unused conditions of the terminals of the microcomputer 20, the connector 22 and the power supply circuit 24 to which the unused wirings are connected.

In the state shown in FIGS. 1 and 2, for example, all of the signal lines 28a to 28d are the unused wirings. Since the unused conditions of the terminals 20a, 20b, 22a and 22b to which the signal lines 28a to 28d correspond are for ground connection, the signal lines 28a to 28d are connected to the conductor 12b3 forming the ground layer through the corresponding connecting portions 30a to 30d. In FIG. 2, the signal line 28c, which is connected to the terminal 22a of the connector 22, is connected to the conductor 12b3 through the connecting portion 30c.

The internal power supply line 28e is also an unused terminal. The internal power supply line 28e is connected to the conductor 12b4, which forms the power supply line, through the connecting portion 30e.

The external power supply line 28f is connected to the external power supply line 34a that forms the main circuit 18. The external power supply line 28f is not directly connected to the terminal of any of the microcomputer 20, the connector 22 and the power supply circuit 24.

The external power supply line 28f is connected to the conductor 12b4, which forms the power supply layer, through the through hole 36b. Therefore, it is not necessary to process the external power supply line 28f as for the unused wiring. The ground pattern 28g is connected to the conductor 12b3, which forms the ground layer, through the through hole (not shown). Therefore, it is not necessary to process the ground pattern 28g as for the unused wiring.

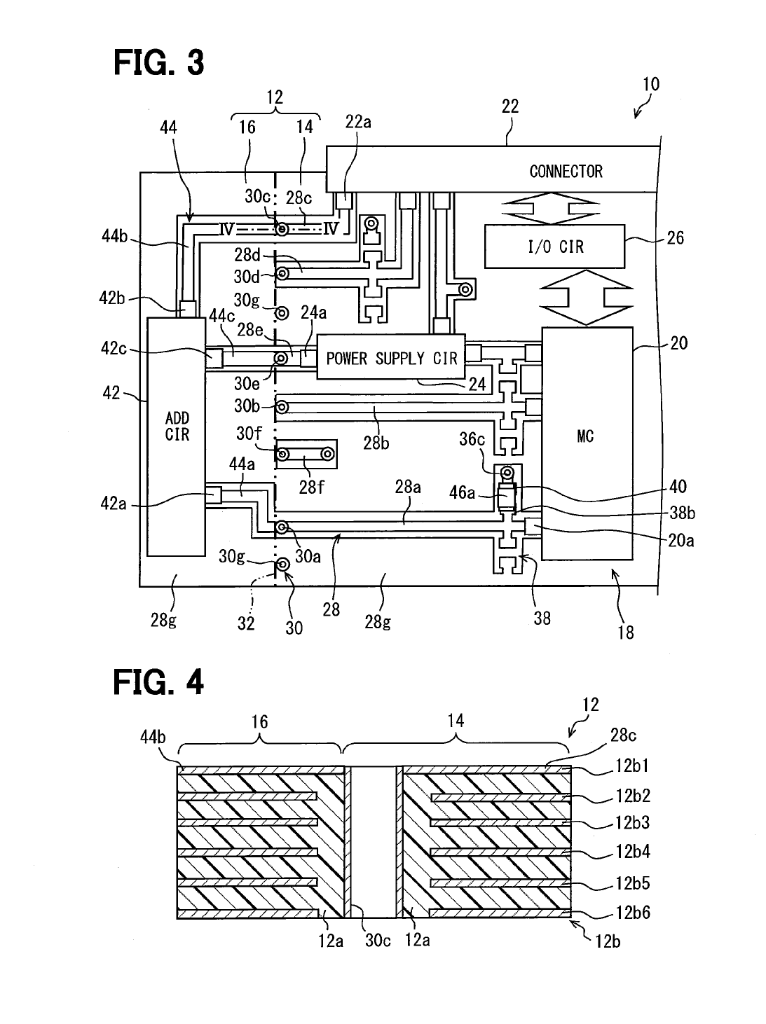

Next, the electronic device 10 to which a function has been added will be described with reference to FIGS. 3 and 4. Components same as or relating to the components of the structure shown in FIGS. 1 and 2 will be designated with the same reference numbers.

The electronic device 10 shown in FIGS. 3 and 4 has an additional circuit 42 in the second region 16 of the multilayer substrate 12, in addition to the structure shown in FIGS. 1 and 2. The additional circuit 42 is provided to add a function relative to the predetermined function realized by the main circuit 18. For example, the additional circuit 42 is configured as a circuit for performing plug-in control in charging of the secondary battery at a charging station or a residential power supply.

The electronic device 10 with the additional circuit 42 is, for example, used for vehicles in high class or vehicles in high grade even in the same type. Further, the electronic device 10 with the additional circuit 42 may be an electronic device to which functions are added according to user's options. Moreover, the electronic device 10 with the additional circuit 42 shown in FIGS. 3 and 4 may also be used as an electronic device at an early stage in mass production considering a design change after the mass production, or may be in a state during development.

The second region 16 of the multilayer substrate 12 is formed with second wirings 44 to electrically connect between the additional circuit 42 and the corresponding connecting portions 30. The second wirings 44 are configured to include the conductors 12b. In the example shown in FIGS. 3 and 4, the second region 16 includes a plurality of the second wirings 44. Each of the second wirings 44 is configured to include at least the conductor 12b1 on the first layer.

Specifically, the second wirings 44 include signal lines 44a and 44b and an internal power supply line 44c. Hereinafter, the signal lines 44a and 44b and the internal power supply line 44c will also be referred to as the second wirings 44a to 44c.

The signal line 44a is disposed on the first layer as a part of the conductor 12b1. The signal line 44a electrically connects between a terminal 42a of the additional circuit 42 and the connecting portion 30a. That is, the additional circuit 42 and the microcomputer 20 are electrically connected to each other through the signal line 44a, the connecting portion 30a and the signal line 28a.

The signal line 44b is disposed on the first layer as a part of the conductor 12b1. The signal line 44b electrically connects between a terminal 42b of the additional circuit 42 and the connecting portion 30c. That is, the additional circuit 42 and the connector 22 are electrically connected to each other through the signal line 44b, the connecting portion 30c and the signal line 28c.

The internal power supply line 44c is disposed on the first layer as a part of the conductor 12b1. The internal power supply line 44c electrically connects between a terminal 42c of the additional circuit 42 and the connecting portion 30e. That is, the additional circuit 42 and the power supply circuit 24 are electrically connected to each other through the internal power supply line 44c, the connecting portion 30e and the internal power supply line 28e.

In the example shown in FIGS. 3 and 4, since the additional circuit 42 is formed, the unused wirings are different from those shown in FIGS. 1 and 2.

For example, the connection between the connecting portion 30a and the conductor 12b3, which forms the ground layer, is cut off. The signal line 28a is connected to the signal line 44a through the connecting portion 30a. The connection between the connecting portion 30c and the conductor 12b3, which forms the ground layer, is cut off. The signal line 28c is connected to the signal line 44b through the connecting portion 30c, as shown in FIG. 4. The connection between the connecting portion 30e and the conductor 12b4, which forms the power supply layer, is cut off. The internal power supply line 28e is connected to the internal power supply line 44c through the connecting portion 30e. Therefore, the signal lines 28b and 28d are the unused wirings. The unused processing for the signal lines 28b and 28d is the same as the unused processing for the unused wirings described in connection with the example shown in FIGS. 1 and 2.

Of the signal lines 28a, 28c and 28e electrically connected to the additional circuit 42, a chip component 46a, such as a resistor or a capacitor, is mounted on the second land 38b of the signal line 28a. Specifically, the chip component 46a is mounted on the second land 38b and the land 40 adjacent to the internal power supply line 34b. Thus, the internal power supply line 34b and the signal line 28a are connected to each other through the chip component 46a.

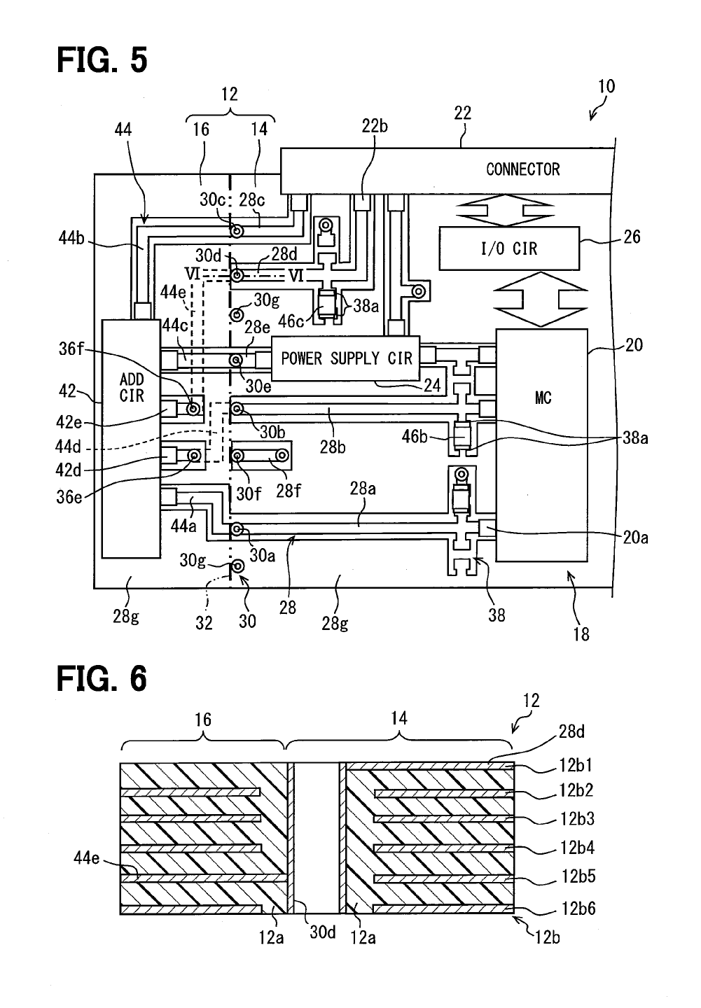

Next, the electronic device 10 to which a function has been further added will be described with reference to FIGS. 5 and 6. Components same as or relating to the components of the structure shown in FIGS. 1 to 4 will be designated with the same reference numbers.

The electronic device 10 shown in FIGS. 5 and 6 has the additional circuit 42 to which a function is further added to the structure shown in FIGS. 3 and 4. For example, a circuit for performing a charging control of the secondary battery by a solar panel mounted on a vehicle roof, or a circuit for performing a pre-air conditioning control for controlling the temperature of a passenger compartment of a vehicle when a user is away from the vehicle is added.

The electronic device 10 with the additional circuit 42 shown in FIGS. 5 and 6 is, for example, used for vehicles in higher class or vehicles of higher grade even in the same type than those shown in FIGS. 3 and 4. Further, the electronic device 10 with the additional circuit 42 may be an electronic device to which functions are further added according to user's options. Moreover, the electronic device 10 shown in FIGS. 5 and 6 may be in a state during development.

In addition to the signal lines 44a and 44b and the internal power supply line 44c, signal lines 44d and 44e are formed in the second region 16 of the multilayer substrate 12. The signal line 44d includes a first portion, a second portion, and a through hole 36e. The first portion of the signal line 44d is formed on the first layer as a part of the conductor 12b1. The second portion of the signal line 44d is formed on the fifth layer as a part of the conductor 12b5. The through hole 36e connects between the first portion and the second portion. In FIG. 5, the second portion of the signal line 44d, which is formed on the fifth layer, is illustrated with a dashed line.

Further, the first portion of the signal line 44d is connected to a terminal 42d of the additional circuit 42, and the second portion of the signal line 44d is connected to the connecting portion 30b. Thus, the signal line 44d electrically connects between the terminal 42d of the additional circuit 42 and the connecting portion 30b. In other words, the microcomputer 20 and the additional circuit 42 are electrically connected to each other through the signal line 28b, the connecting portion 30b and the signal line 44d.

The signal line 44e includes a first portion, a second portion and a through hole. The first portion of the signal line 44e is formed on the first layer as a part of the conductor 12b1. The second portion of the signal line 44e is formed on the fifth layer as a part of the conductor 12b5. The through hole of the signal line 44e connects between the first portion and the second portion. In FIG. 5, the second portion of the signal line 44e, which is formed on the fifth layer, is illustrated with a dashed line.

Further, the first portion of the signal line 44e is connected to a terminal 42e of the additional circuit 42, and the second portion of the signal line 44e is connected to a connecting portion 30d. Thus, the signal line 44e electrically connects between the terminal 42e of the additional circuit 42 and the connecting portion 30d. In other words, the connector 22 and the additional circuit 42 are electrically connected to each other through the signal line 28d, the connecting portion 30d and the signal line 44e.

In the example shown in FIGS. 5 and 6, the connection between the connecting portion 30c and the conductor 12b3, which forms the ground layer, is cut off. The signal line 28b is connected to the signal line 44d through the connecting portion 30b. As shown in FIG. 6, the connection between the connecting portion 30d and the conductor 12b3, which forms the ground layer, is cut off, and the signal line 28d is connected to the signal line 44e through the connecting portion 30d. Thus, there is no unused wiring.

A chip component 46b, such as a resistor and a capacitor, is mounted on the first land 38a that is disposed between the signal line 28b, which is electrically connected to the additional circuit 42, and the signal line 28b. Likewise, a chip component 46c is mounted on the first land 38a that is disposed between the signal line 28d and the ground pattern 28g.

Next, effects of the electronic device 10 of the present embodiment will be described.

In the electronic device 10 shown in FIGS. 1 to 6, the multilayer substrate 12 includes the first region 14 in which the main circuit 18 is formed and the second region 16 in which the additional circuit 42 is formed. The first region 14 and the second region 16 are divided from each other on the multilayer substrate 12. In addition, the connecting portion 30 for connecting the main circuit 18 and the additional circuit 42 is disposed over all of the layers at the end of the first region 14 adjacent to the second region 16. The main circuit 18 is connected to the connecting portion 30 through the first wiring 28.

In this way, the first wirings 28 can be connected to the conductors 12b (12b1 to 12b6) of any layers through the connecting portions 30. Therefore, even if the additional circuit 42 to be added in the second region 16 has any specification, the main circuit 18 and the additional circuit 42 can be electrically connected to each other without changing the specification of the first region 14, as shown in FIGS. 1 to 6. Namely, a function can be added without changing the first region 14.

In other words, flexibility in design can improve. In the electronic device 10 shown in FIG. 5, for example, the second portion of the signal line 44e is provided by the portion of the conductor 12b5 on the fifth layer. In this case, therefore, the main circuit 18 and the additional circuit 42 can be connected to each other away from the internal power supply line 44c on the first layer.

Evaluations for noise and the like may be conducted to the entirety of the multilayer substrate 12 only at a first time. When and after the design of only the second region 16 is changed, the evaluations may be conducted only for the second region 16.

For example, the first region 14 can be made in common for multiple types of vehicle. As another example, the first region 14 can be made in common for different grades of the vehicles of the same type. As further another example, the first region 14 can be made in common for vehicles functions of which are optionally selected by users. In such cases, the manufacturing costs reduce.

Accordingly, the workloads necessary in association with the design change of the substrate 12 can be reduced, and the increase in manufacturing costs can be reduced, as compared with a case where the whole substrate needs to be reviewed in every design change.

The first region 14 and the second region 16 are provided in the same multilayer substrate 12, that is, in one multilayer substrate 12. Therefore, the manufacturing costs reduce, as compared with a structure in which the first region and the second region are provided by separate substrates.

As described above, the main circuit 18 can be electrically connected to the additional circuit 42 through the connecting portion 30 formed in the multilayer substrate 12. Specifically, the main circuit 18 and the additional circuit 42 are electrically connected to each other through the first wiring 28, the connecting portion 30 and the second wiring 44. Therefore, a separate part, such as a connector, that is separate from the multilayer substrate 12 is not necessary to connect the main circuit 18 and the additional circuit 42 to each other. As such, the number of component parts can be reduced. Further, the manufacturing costs can be reduced.

In a case where a connector is used to connect between the main circuit 18 and the additional circuit 42, terminals of the connector are stressed when being engaged with the circuit, or stressed by vibrations of the vehicle. In such a case, there may be a problem in the reliability of electrical connection between the main circuit and the additional circuit.

In the present embodiment, on the other hand, the main circuit 18 and the additional circuit 42 are connected to each other through the connecting portion 30 formed in the multilayer substrate 12, without using the separate connector. Therefore, the reliability of the electrical connection between the main circuit 18 and the additional circuit 42 improves.

In the present embodiment, as shown in FIGS. 1 and 2, of the first wirings 28a to 28g, the unused wiring that is not electrically connected to the additional circuit 42 is processed according to the unused condition of the terminals of the microcomputer 20, the connector 22, and the power supply circuit 24 to which the unused wiring is connected. For example, the signal lines 28a to 28d are connected to the conductor 12b3, which forms the ground layer on the third layer, according to the unused conditions of the terminals 20a, 20b, 22a, 22b to which the signal lines 28a to 28d are connected. Therefore, even in the unused state, malfunctions of the microcomputer 20 and the like are restricted.

In the present embodiment, particularly, the unused wirings are processed for the unused state through the connecting portion 30 disposed over all of the layers. Therefore, when the unused wiring needs to be used by the addition of the additional circuit 42, the connection between the connecting portion 30 and the conductor 12b may be simply cut off. In this way, the unused processing and its release are easily made.

The first wirings 28 (28a, 28b, 28d) has the lands 38 on which the chip components 46a to 46c can be mounted. Since the lands 38 are provided in the first region 14 beforehand, the chip components 46a to 46c, such as the resistor and the capacitor, can be mounted on the lands 38 according to the additional circuit 42. With this, it is possible to deal with various types of signals, such as a signal requiring a phase fixing. For example, a signal that is 0 V and on at a normal time, and is 5 V and off when a predetermined condition satisfied is inputted into the signal lines 28d and 44e shown in FIG. 5 from an external device. In this case, when the resistor is mounted as the chip component 46c, the voltage level of the signal lines 28d and 44e can be kept at 0 V.

The exemplary embodiment of the present disclosure is described hereinabove. However, the present disclosure is not limited to the exemplary embodiment described above, but may be implemented in various other ways without departing from the gist of the present disclosure.

The shape, the number and the arrangement of the main circuit 18, the additional circuit 42, the first wirings 28, the connecting portions 30 and the second wirings 44 may not be limited to the examples described hereinabove.

In the embodiment described above, the electronic device 10 is an electronic control device that integrally controls the entirety of the driving system of the hybrid vehicle by the main circuit 18. However, the electronic device 10 may not be limited to the example described above.

The electronic device 10 at least includes the first region 14 in which the main circuit 18 for implementing the predetermined function is formed, and the second region 16 to which the additional circuit 42 for adding the function relative to the predetermined function can be formed. For example, the electronic device 10 may be employed to any other electronic devices for vehicles. For example, the electronic device 10 may be employed to electronic devices for any other purposes, such as for consumer electronic devices, other than the vehicles.

The electronic device 10 may employ a structure in which the main circuit 18 for integrally controlling the whole driving system of the hybrid vehicle is formed in the first region 14, and the additional circuit 42 for realizing a function of a sensor for sensing a physical quantity for a purpose of control is formed in the second region 16. In such a case, the sensor may include only a sensing portion, or may also include a processing circuit for processing an output from the sensing portion.

The electronic device 10 may employ a structure in which the main circuit 18 for realizing a function of a first sensor is formed in the first region 14 and the additional circuit 42 for realizing a function of a second sensor is formed in the second region 16. In such a case, the main circuit 18 and/or the additional circuit 42 may only have a sensing portion.

The structure of the connecting portion 30 is not limited to the through hole. The connecting portion 30 may have any structure as long as the connecting portion 30 is arranged to extend over all of the layers of the multilayer substrate 12 in which the conductors 12b are disposed, and electrically connected to the conductor 12b of each layer. For example, the connecting portion may be provided by a connection via.

In the embodiment described above, in a case where the additional circuit 42 is not formed in the second region 16, the electronic device 10 includes the first region 14 as well as the second region 16 on which the additional circuit 42 is not formed. However, when the additional circuit 42 is not formed in the second region 16, the multilayer substrate 12 may be cut at the boundary 32 by a router or the like, to have only the first region 14. Therefore, in the case where the additional function is not necessary, the electronic device 10 can be reduced in size.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. An electronic device comprising
a multilayer substrate including a plurality of conductors layered, the multilayer substrate having a first region and a second region divided in a planar direction of the multilayer substrate perpendicular to a layered direction of the conductors, the first region being provided with a main circuit that realizes a predetermined function, the second region being provided for having an additional circuit therein for adding a function to the predetermined function,
wherein the first region includes:
a first wiring for electrically connecting the main circuit to the additional circuit; and
a connecting portion being electrically connected to the first wiring, the connecting portion being located at an end of the first region adjacent to the second region and extending in the multilayer substrate to correspond to all of the conductors layered to enable the first wiring to connect to any of the conductors, and
wherein the main circuit is electrically connectable to the additional circuit through the first wiring and the connecting portion.

2. The electronic device according to claim 1, wherein
the first wiring is one of a plurality of first wirings,
the connecting portion is one of a plurality of connecting portions,
the main circuit includes a microcomputer, a connector, and a power supply circuit that converts a voltage of an external power supplied through the connector, and
terminals of the microcomputer, the connector and the power supply circuit are correspondingly connected to the connecting portions through the first wirings.

3. The electronic device according to claim 2, wherein
the plurality of first wirings includes an unused wiring that is not electrically connected to the additional circuit, and
the unused wiring is processed according to an unused condition of the terminal to which the unused wiring is connected.

4. The electronic device according to claim 3, wherein
the unused wiring is a signal line,
the unused condition is one of a connection to a ground and a connection to a power supply, and
the unused wiring is connected to a corresponding one of the conductors according to the unused condition of the terminal through the connecting portion.

5. The electronic device according to claim 1, wherein
the second region is provided with the additional circuit,
the second region includes a second wiring electrically connecting between the additional circuit and the connecting portion, and
the additional circuit is electrically connected to the main circuit through the second wiring, the connecting portion and the first wiring.

6. The electronic device according to claim 1, wherein
the first wiring includes a land for receiving a chip component thereon.
